(19) United States
(12) Patent Application Publication
(10) Pub. No.: US 2022/0039277 A1
(43) Pub. Date: Feb. 3, 2022

(54) FOLDABLE DISPLAY DEVICE AND FOLDABLE TERMINAL

(71) Applicant: SHENZHEN ROYOLE TECHNOLOGIES CO., LTD., Shenzhen (CN)

(72) Inventor: Hewen Shen, Shenzhen (CN)

(21) Appl. No.: 17/387,637

(22) Filed: Jul. 28, 2021

(30) Foreign Application Priority Data
Jul. 31, 2020 (CN) 202010760129.8

(51) Int. Cl. H05K 5/02

(52) U.S. Cl. CPC H05K 5/0226

(57) ABSTRACT

A foldable display device and a foldable terminal are provided. The foldable display device comprises a flexible screen, a folding mechanism, a bendable flattening sheet, and two sets of sliding mechanisms. The folding mechanism, the flattening sheet and the flexible screen are laminated in sequence, and are fixedly connected to each other at a middle folding position, so as to avoid arching of the flexible screen. The two sets of sliding mechanisms each include a first spring, a first sliding member, a second spring, and a second sliding member connected in sequence; two ends of the flattening sheet are fixed to the first sliding members of the two sets of sliding mechanisms respectively, and two ends of the flexible screen are fixed to the second sliding members of the two sets of sliding mechanisms respectively.

### CROSS-REFERENCE TO RELATED APPLICATIONS

This application claims priority to Chinese Patent Application No. 202010760129.8, filed with the Chinese Patent Office on Jul. 31, 2020, entitled “Foldable Display Device and Foldable Terminal”, which is incorporated herein by reference in its entirety.

### TECHNICAL FIELD

The present disclosure relates to the technical field of foldable display, in particular to a foldable display device and a foldable terminal.

### BACKGROUND ART

A flexible screen is formed by attaching multiple layers of material by an OCA (optically clear adhesive). After bending, each layer will have slight relative displacement, and shear deformation occurs in the OCA. When the flexible screen is unfolded after the bending, shear deformation of the OCA cannot be recovered in time, then arching is phenomenon may occur in a bending region. A foldable terminal realizes folding and unfolding by means of a folding mechanism, while a surface of the folding mechanism itself can hardly be ensured to be smooth and neat, thus it is hard to ensure flatness of the flexible screen. In addition, as the foldable mechanism and the flexible screen have different folding and bending radii, the flexible screen will be pulled in the process of unfolding and folding, which affects the reliability of the flexible screen, and cannot overcome the problem of arching of the flexible screen in the bending region.

### SUMMARY

Embodiments of the present disclosure disclose a foldable display device and a foldable terminal, which can ensure the reliability and the flatness in unfolding of the flexible screen.

In a first aspect, an embodiment of the present disclosure discloses a foldable display device, including a flexible screen, a folding mechanism, a bendable flattening sheet, and two sets of sliding mechanisms, wherein the folding mechanism, the flattening sheet, and the flexible screen are laminated in sequence, and the three are fixedly connected to each other at a middle folding position;

the two sets of sliding mechanisms each include a first spring, a first sliding member, a second spring, and a second sliding member; the two first springs are fixedly connected to two ends of the folding mechanism respectively; the first spring, the first sliding member, the second spring, and the second sliding member in each set of sliding mechanism are connected in sequence in a direction away from the folding mechanism, and the first springs and the second springs are configured to generate elastic deformation so as to make the first sliding members and the second sliding members slide;

two ends of the flattening sheet are fixedly connected to the first sliding members of the two sets of sliding mechanisms respectively, and the two ends of the flexible screen are fixedly connected to the second sliding members of the two sets of sliding mechanisms, respectively.

In the above, the first springs and the second springs are all coil springs.
In the above, each end of the folding mechanism is provided with a first positioning hole, each of the first sliding member is provided with a second positioning hole and a third positioning hole, each of the second sliding member is provided with a fourth positioning hole, two ends of the each first spring are fixed in the first positioning hole and the second positioning hole respectively, and two ends of the each second spring are fixed in the third positioning hole and the fourth positioning hole, respectively.
In the above, a plurality of the first springs and a plurality of the second springs are provided, the plurality of first springs are arranged side by side along the folding axis of the folding mechanism, and the plurality of second springs are arranged side by side along the folding axis of the folding mechanism.

In the above, each of the first sliding members is in an elongated shape arranged along the folding axis of the folding mechanism.

In the above, the second sliding member is in a square plate shape.

In the above, when the foldable display device is in the unfolded state, the two second sliding members and the flattening sheet together form a support surface for the flexible screen.

In the above, each set of the sliding mechanism further includes a guide rod, one end of the guide rod is fixedly connected to the end of the folding mechanism, an axial direction of the guide rod is set along an arrangement direction of the first sliding member and the second sliding member, and the first sliding member and the second sliding member are both slidably connected to the guide rod.

In the above, the flattening sheet is provided with a middle connecting column at the middle folding position, the folding mechanism is provided with a middle connecting hole at the middle folding position, the middle connecting column is fixed in the middle connecting hole by a middle screw, and the folding mechanism is located between the middle screw and the flattening sheet.

In the above, two ends of the flattening sheet are each provided with an end connecting column, the first sliding member of each set of sliding mechanism is provided with an end connecting hole, the end connecting columns at the two ends of the flattening sheet are each fixed into the end connecting hole of the first sliding member of the corresponding set of sliding mechanism by an end screw, and each of the first sliding members is located between the middle screw and the flattening sheet.

In the above, the folding mechanism includes a plurality of chain links, the plurality of chain links are hinged in sequence along an arrangement direction of the two sets of sliding mechanisms, a direction of rotation axis of each chain link is parallel to a direction of folding axis of the foldable display device, and the chain link located in the middle of the plurality of chain links is fixedly connected to the flattening sheet and the flexible screen.

In the above, when each of the first sliding members moves a maximum distance relative to the folding mechanism, a gap between the each first sliding member and the folding mechanism is S₁,

$${S}_{1} \geq \frac{{D}_{1} \cdot π}{2} ,$$

where D₁ indicates a distance between neutral layers of the folding mechanism and the flattening sheet when the folding mechanism and the flattening sheet are both bent.

In the above, when each of the second sliding members moves a maximum distance relative to the corresponding first sliding member, a gap between the each second sliding member and the corresponding first sliding member is S₂,

$${S}_{2} \geq \frac{{D}_{2} \cdot π}{2} ,$$

where D₂ indicates a distance between neutral layers of the flexible screen and the flattening sheet when the flexible screen and the flattening sheet are both bent.

In another aspect, the present disclosure further provides a foldable terminal, including the foregoing foldable display device.

By implementing the embodiments of the present disclosure, the folding mechanism, the flattening sheet, and the flexible screen are fixedly connected to each other at the middle folding position, wherein in the folding and unfolding, the three are relatively fixed at the middle folding position, and only two ends of each of them may move relatively, which can avoid arching of the flexible screen; with the flattening sheet, the flatness of the flexible screen in the unfolding can be further ensured; with the first sliding members and the second sliding members in the two sets of sliding mechanisms, two ends of the flattening sheet and the flexible screen can be enabled to move relative to the folding mechanism, so as to compensate for the arc length difference caused by different bending radii, thereby avoiding pulling the flexible screen and the flattening sheet, and ensuring the reliability of the flexible screen; with the elastic deformation of the first springs and the second springs, spaces for movement of the first sliding members and the second sliding members relative to the folding mechanism can be provided, and a buffer force and a restoring force are generated for the movement of the first sliding members and the second sliding members, so as to facilitate the folding and unfolding.

### BRIEF DESCRIPTION OF DRAWINGS

Accompanying drawings used in the embodiments of the present disclosure are introduced below.

FIG. 1 is a perspective view of a foldable display device, in an exploded state, provided in an embodiment of the present disclosure;

FIG. 2 is a sectional view of the foldable display device in FIG. 1 in an exploded state;

FIG. 3 is a structural schematic view of the foldable display device in FIG. 1 in a folded state; and

FIG. 4 is a sectional view of the foldable display device in FIG. 1 in an unfolded state including guide rods.

### DETAILED DESCRIPTION OF EMBODIMENTS

The embodiments of the present disclosure are described below in conjunction with accompanying drawings in the embodiments of the present disclosure.

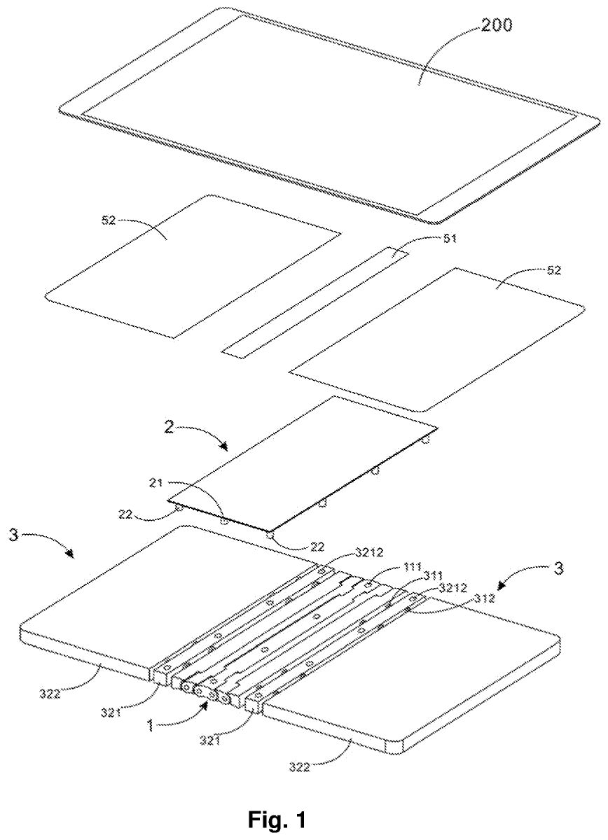

Referring to FIG. 1, FIG. 1 is a foldable display device provided in an embodiment of the present disclosure, including a flexible screen 200, a folding mechanism 1, a bendable flattening sheet 2, and two sets of sliding mechanisms 3. The folding mechanism 1 is configured to enable the whole foldable display device to be folded and unfolded, wherein the folding mechanism 1, the flattening sheet 2, and the flexible screen 200 are laminated in sequence, that is, the flattening sheet 2 is laminated between the flexible screen 200 and the folding mechanism 1, and the three are fixedly connected to each other at a middle folding position of the folding mechanism 1. When the folding mechanism 1 is folded or unfolded, the flattening sheet 2 and the flexible screen 200 are folded and unfolded simultaneously, and the flattening sheet 2 enables the flexible screen 200 to keep flat in an unfolded state. The two sets of sliding mechanisms 3 are provided at two ends of a hinge mechanism respectively, and the two sets of sliding mechanisms 3 are connected to the flattening sheet 2 and the flexible screen 200, so that two ends of the flattening sheet 2 and two ends of the flexible screen 200 can slide relative to two ends of the folding mechanism 1, thereby compensating for the difference in arc length caused by different bending radii of the folding mechanism 1, the flattening sheet 2, and the flexible screen 200.

The two sets of sliding mechanisms 3 have the same structure, and are symmetrically arranged at two ends of the folding mechanism 1 with a plane where a folding axis of the folding mechanism 1 is located being a symmetry plane. In the present embodiment, one set of sliding mechanism 3 therein is taken as an example for detailed description.

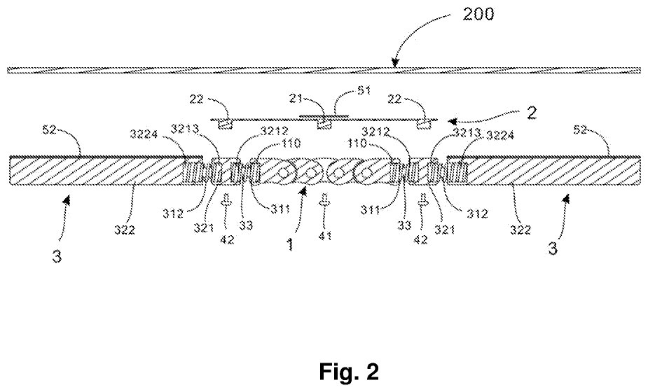

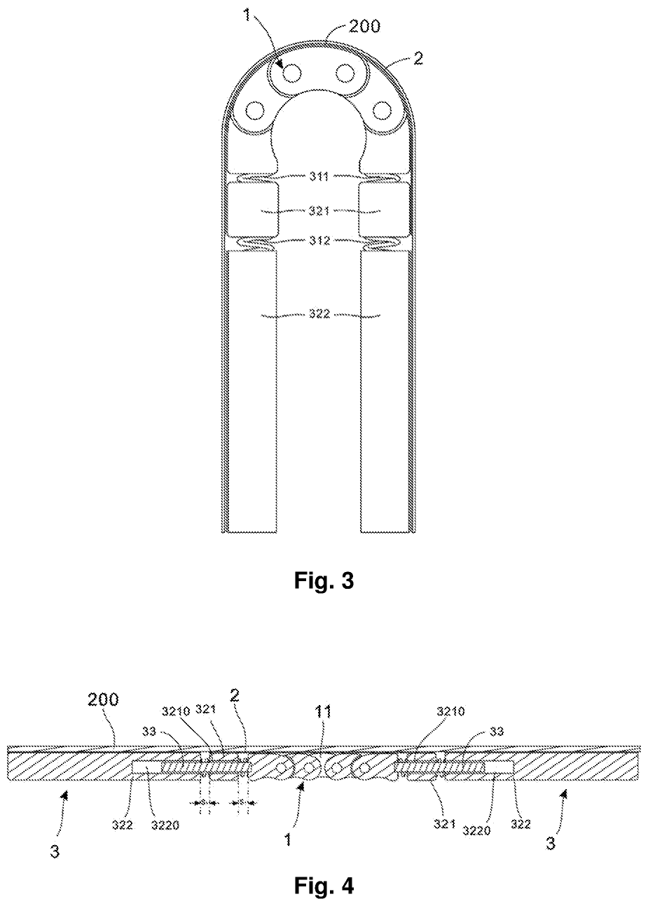

In conjunction with what is shown in FIG. 2 and FIG. 3, the two sets of sliding mechanisms 3 each include a first spring 311, a first sliding member 321, a second spring 312, and a second sliding member 322. The two first springs 311 of the two sets of sliding mechanisms 3 are fixedly connected to two ends of the folding mechanism 1 respectively, and the first spring 311, the first sliding member 321, the second spring 312, and the second sliding member 322 are connected in sequence in a direction away from the folding mechanism 1. When the foldable display device is folded or unfolded, the first springs 311 and the second springs 312 generate elastic deformation so as to make the first sliding members 321 and the second sliding members 322 slide.

Two ends of the flattening sheet 2 are fixedly connected to the first sliding members 321 of the two sets of sliding mechanisms 3 respectively, and the two ends of the flexible screen 200 are fixedly connected to the second sliding members 322 of the two sets of sliding mechanisms 3 respectively. When the foldable display device is folded or unfolded, the first sliding members 321 can move simultaneously with the ends of the flattening sheet 2, and the second sliding members 322 can move simultaneously with the ends of the flexible screen 200. The flexible screen 200, the flattening sheet 2, and the folding mechanism 1 are fixedly connected to each other at the middle folding position. When the foldable display device is folded or unfolded, the flexible screen 200, the flattening sheet 2, and the folding mechanism 1 are kept relatively fixed at the middle folding position, and two ends of each of the flexible screen, the flattening sheet, and the folding mechanism can move relatively, thereby compensating for the difference in arc length of the three due to folding and bending, and avoiding the flexible screen 200 and the flattening sheet 2 from being extruded or stretched to be damaged.

The first spring 311 is provided between the first sliding member 321 and the folding mechanism 1, and the second spring 312 is provided between the first sliding member 321 and the second sliding member 322. With the elastic deformation of the first spring 311 and the second spring 312, a space for movement of the first sliding member 321 and the second sliding member 322 relative to the folding mechanism 1 can be provided, and a buffer force and a restoring force are generated for the movement of the first sliding member 321 and the second sliding member 322. In the present embodiment, as shown in FIG. 2, when the foldable display device is in an unfolded state, that is, when the flattening sheet 2 of the foldable display device is unfolded to be in a flat and straight state, the first spring 311 and the second spring 312 are in a natural state, at this time, the first spring 311 and the second spring 312 are not subjected to an external force; when the foldable display device is in the folded state, the first spring 311 and the second spring 312 are in an elastically deformed state, at this time, the first spring 311 and the second spring 312 may provide a force for the unfolding of the foldable display device, so as to facilitate the unfolding of the foldable display device. Herein, in other embodiments, it is also feasible that when the foldable display device is in the folded state, the first spring 311 and the second spring 312 are in a natural state in which the first spring and the second spring are not subjected to an external force, and when the foldable display device is in the unfolded state, the first spring 311 and the second spring 312 are in the elastically deformed state, at this time, the first spring 311 and the second spring 312 may provide a force for the folding of the foldable display device.

In the present embodiment, the first spring 311 and the second spring 312 are both coil springs, so as to facilitate their assembly and connection with the first sliding member 321, the second sliding member 322, and the folding mechanism 1. Herein, in other embodiments, the first spring 311 and the second spring 312 may also be any one of disc springs, annular springs, plate springs, and torsion bar springs. In the present embodiment, the first spring 311 and the second spring 312 both are of the same shape, and certainly, in other embodiments, the two may also be of different shapes.

A plurality of first springs 311 are provided and the plurality of first springs 311 are arranged side by side along the folding axis of the folding mechanism 1. A plurality of second springs 312 are provided and the plurality of second springs 312 are arranged side by side along the folding axis of the folding mechanism 1. By utilizing the plurality of first springs 311 and the plurality of second springs 312, it can be ensured that the first sliding member 321 and the second sliding member 322 are subjected to a uniform force.

Each end of the folding mechanism 1 is provided with a first positioning hole 110, the first sliding member 321 is provided with a second positioning hole 3212 and a third positioning hole 3213, and the second sliding member 322 is provided with a fourth positioning hole 3224. Two ends of the first spring 311 are fixed in the first positioning hole 110 and the second positioning hole 3212 respectively, and two ends of the second spring 312 are fixed in the third positioning hole 3213 and the fourth positioning hole 3224 respectively. By utilizing the plurality of positioning holes, the assembly and positioning of the first spring 311 and the second spring 312 can be facilitated.

As shown in FIG. 1, the first sliding member 321 is in an elongated shape arranged along the folding axis of the folding mechanism 1, so as to ensure balanced movement of ends of the flattening sheet 2 at respective positions, and facilitate movement of the ends of the flattening sheet 2 relative to the ends of the folding mechanism 1. Herein, in other embodiments, the first sliding member 321 may also be formed of a plurality of square blocks, where the plurality of square blocks are arranged along a direction of the folding axis of the folding mechanism 1, the plurality of square blocks are all fixedly connected to the end of the flattening sheet 2, the first spring 311 is provided between each square block and the folding mechanism 1, and the second spring 312 is provided between each square block and the second sliding member 322.

As shown in FIG. 1, the second sliding member 322 is in a square plate shape, and with the second sliding member 322 in the square plate shape, a connection area between the second sliding member 322 and the flexible screen 200 may be increased, thereby ensuring stability of movement of the flexible screen 200, and avoiding pulling the flexible screen 200. The second sliding member 322 may be a sheet metal part in a hollow structure, so that components such as a circuit board and a battery of the whole device are provided inside the second sliding member.

When the foldable display device is in the unfolded state, the two second sliding members 322 and the flattening sheet 2 together form a support surface for the flexible screen 200. The two square plate-shaped second sliding members 322 and the flattening sheet 2 can form in the unfolded state a flat and straight support surface, thus effectively supporting the flexible screen 200, and enabling a user to conveniently perform click and touch operations on the flexible screen 200.

In the present embodiment, the first spring 311 and the second spring 312 may be two separate components, and in other embodiments, the first spring and the second spring may be embodied as one component, that is, the first spring 311 and the second spring 312 are integrally formed, and a longer spring is adopted for the two. The first sliding member 321 is fixed in the middle of the spring, and the second sliding member 322 and the folding mechanism 1 are connected to two ends of the spring, respectively.

Further, as shown in FIG. 2 and FIG. 4, the sliding mechanism 3 further includes a guide rod 33, one end of the guide rod 33 is fixedly connected to the end of the folding mechanism 1, an axial direction of the guide rod 33 is set along an arrangement direction of the first sliding member 321 and the second sliding member 322, and the first sliding member 321 and the second sliding member 322 are both slidably connected to the guide rod 33. More specifically, the first sliding member 321 is provided with a first guide hole 3210, the second sliding member 322 is provided with a second guide hole 3220, and the guide rod 33 penetrates through the first guide hole 3210 and the second guide hole 3220, so that the first sliding member 321 and the second sliding member 322 are both slidably engaged with the guide rod 33. With the guide rod 33, the stability of movement of the first sliding member 321 and the second sliding member 322 may be ensured. Herein, the first spring 311 and the second spring 312 may not be fixed by positioning holes, but are sheathed over the guide rod 33, and the two ends of the first spring 311 may just abut against the folding mechanism 1 and the first sliding member 321, without the need of fixing. Likewise, the two ends of the second spring 312 may just abut against the first sliding member 321 and the second sliding member 322, without the need of fixing.

The flattening sheet 2 is located between the flexible screen 200 and the folding mechanism 1, which can avoid damage to the flexible screen 200 caused by uneven structure of the folding mechanism 1, and ensure the flatness and reliability of the flexible screen 200 during the folding and unfolding.

As shown in FIG. 1 and FIG. 2, the flattening sheet 2 is provided with a middle connecting column 21 at the middle folding position, the folding mechanism 1 is provided with a middle connecting hole 111 at the middle folding position, the middle connecting column 21 is fixed in the middle connecting hole 111 by a middle screw 41, and the folding mechanism 1 is located between the middle screw 41 and the flattening sheet 2, so that the flattening sheet 2 and the folding mechanism 1 are firmly and reliably connected to each other, and that the flatness of one side of the flattening sheet 2 facing the flexible screen 200 can be ensured. A plurality of middle connecting columns 21 may be provided, and arranged along the folding axis of the folding mechanism 1, and correspondingly, a plurality of middle connecting holes 111 also may be provided and arranged along the folding axis of the folding mechanism 1. Herein, the flattening sheet 2 may also be fixedly connected to the folding mechanism 1 through screws, welding or in other manners, or the middle connecting column 21 is in interference fit with the middle connecting hole 111.

Two ends of the flattening sheet 2 are each provided with an end connecting column 22, the first sliding member 321 of each set of sliding mechanism 3 is provided with an end connecting hole 3212, the end connecting columns 22 at two end of the flattening sheet 2 are each fixed into the end connecting hole 3212 of the first sliding member 321 of corresponding set of sliding mechanism 3 by an end screw 42, and the first sliding member 321 is located between the middle screw 42 and the flattening sheet 2, so that the flattening sheet 2 is firmly and reliably connected to the first sliding member 321, and moreover, the flatness of one side of the flattening sheet 2 facing the flexible screen 200 can be ensured. A plurality of end connecting columns 22 may be provided, and arranged along the folding axis of the folding mechanism 1, and correspondingly, a plurality of end connecting holes 3212 also may be provided and arranged along the folding axis of the folding mechanism 1. Herein, the flattening sheet 2 also may be fixedly connected to the first sliding member 321 through screws, welding or in other manners, or the end connecting column 22 is in interference fit with the end connecting hole 3212, or the ends of the flattening sheet 2 are each provided with a structure such as a hook to allow it to be connected to the corresponding first sliding member 321.

In the present embodiment, the flattening sheet 2 adopts a steel sheet having elasticity to ensure its structural strength and flatness, and allow it to be easily unfolded after bending. Certainly, in other embodiments, the flattening sheet 2 may also be made of other bendable materials, for example, various alloy materials.

As shown in FIG. 1 and FIG. 2, in the present embodiment, the portion of the flexible screen 200 at the middle folding position is fixedly connected to the flattening sheet 2 through a middle double-sided adhesive 51, and in other embodiments, the flexible screen 200 and the flattening sheet 2 may also be bonded to each other by other means or fixed to each other by screws. In the present embodiment, the portion of the flexible screen 200 at the end position is fixedly connected to the second sliding member 322 through an end double-sided adhesive 52, and in other embodiments, the flexible screen 200 and the second sliding member 322 also may be bonded to each other by other means or fixed to each other by screws.

In the present embodiment, the folding mechanism 1 is a hinge mechanism with multiple chain links hinged in sequence. Specifically, as shown in FIG. 4, the folding mechanism includes a plurality of chain links 11, the plurality of chain links 11 are hinged in sequence along the arrangement direction of the two sets of sliding mechanisms 3, a direction of rotation axis of each chain link 11 is parallel to the direction of folding axis of the foldable display device, and the chain link located in the middle of the plurality of chain links 11 is fixedly connected to the flattening sheet 2 and the flexible screen 200. Preferably, the number of chain links 11 is odd, so as to facilitate the chain link located at the middle position being fixedly connected to the flattening sheet 2 and the flexible screen 200. In the present embodiment, each chain link 11 is in an elongated shape, with a length direction being the direction of rotation axis of the chain link 11, and the whole foldable display device may use just one folding mechanism 1. In other embodiments, each chain link 11 may also be in a block shape, the foldable display device may include two or more folding mechanisms 1, and the two or more folding mechanisms 1 are arranged along the direction of rotation axis of the chain links 11. In addition, in other embodiments, the folding mechanism 1 also may be any other mechanism that can realize folding and unfolding.

In the present embodiment, the foldable display device is mainly applicable to the case where the flexible screen is folded outwardly, that is, the flexible screen 200 is located outside the whole device after the foldable display device is folded. As shown in FIG. 3, in the folded state, each first sliding member 321 moves a minimum distance relative to the folding mechanism 1, each second sliding member 322 moves a minimum distance relative to the first sliding member 321, in this case, each first sliding member 321 and the folding mechanism 1 may be in abutment with each other or may maintain a proper gap therebetween, and each second sliding member 32 and the corresponding first sliding member 321 also may be in abutment with each other or may maintain a proper gap therebetween. In the folded state, the flexible screen 200, the flattening sheet 2, and the folding mechanism 3 are arranged in sequence inwardly from outside, and the bending radii of the flexible screen 200, the flattening sheet 2, and the folding mechanism 3 are in a descending order.

When the foldable display device is unfolded from the folded state to the unfolded state, as the bending radii of the flexible screen 200, the flattening sheet 2, and the folding mechanism 3 are different in the folded state, moving distances of two ends of each of the three are different when the three are unfolded.

In the above, in the folded state, the bending radius of the flattening sheet 2 is larger compared with the folding mechanism 1. In the unfolding process, the moving distance of the two ends of the flattening sheet 2 is also larger compared with the moving distance of the two ends of the folding mechanism 1. The two first sliding members 321 are fixedly connected to two ends of the flattening sheet 2 to slide together. The moving distance of the two first sliding members 321 is also larger compared with the moving distance of the two ends of the folding mechanism 3. The two first sliding members 321 will generate relative movement relative to the two ends of the folding mechanism 3, respectively. The relative displacement between the two is

$$\frac{( R + {D}_{1} ) \cdot π - R \cdot π}{2} = \frac{{D}_{1} \cdot π}{2} ,$$

where R indicates the bending radius of the folding mechanism 1 in the folded state, D₁ indicates a distance between neutral layers of the folding mechanism and the flattening sheet when the folding mechanism 1 and the flattening sheet 2 are bent, the bending radius of the flattening sheet 2 in the folded state is R+D₁, half of the difference between semicircular arc lengths formed by the neutral layers of the flattening sheet 2 and the folding mechanism 1 is the relative displacement of the two ends of the flattening sheet 2 with respect to the two ends of the folding mechanism 1, that is, relative displacement of the first sliding member 321 with respect to the end of the folding mechanism 1. Through the sliding of the first sliding member 321, in the unfolding process, the first sliding member 321 moves in a direction away from the folding mechanism 1, then the arc length difference between the flattening sheet 2 and the folding mechanism 1 during bending can be compensated. As shown in FIG. 4, in the unfolded state of the foldable display device, the first sliding member 321 moves a maximum distance relative to the folding mechanism 1, and in order to ensure normal movement of the flattening sheet 2 and the folding mechanism 1, at this time, a gap S₁ between the first sliding member 321 and the folding mechanism 1 should be greater than or equal to the above relative displacement, i.e.,

$${S}_{1} \geq \frac{{D}_{1} \cdot π}{2} .$$

In the folded state, the bending radius of the flexible screen 200 is larger compared with that of the flattening sheet 2. In the unfolding process, the moving distances of the two ends of the flexible screen 200 are also larger compared with the moving distances of the two ends of the flattening sheet 2. The two second sliding members 322 are fixedly connected to two ends of the flexible screen 200 to slide together. The two first sliding members 321 are fixedly connected to two ends of the flattening sheet 2 to slide together. The moving distances of the two second sliding members 322 are also larger compared with those of the two first sliding members 321. The first sliding member 321 and the second sliding member 322 will generate relative movement, and the relative displacement between the two is

$$\frac{( τ + {D}_{2} ) \cdot π - r \cdot π}{2} = \frac{{D}_{2} \cdot π}{2} ,$$

where r indicates the bending radius of the flattening sheet 2 in the folded state, D₂ indicates a distance between neutral layers of the flattening sheet and the flexible screen when the flattening sheet 2 and the flexible screen 200 are bent, the bending radius of the flexible screen 200 in the folded state is r+D₂, half of the difference between semicircular arc lengths formed by the neutral layers of the flattening sheet 2 and the flexible screen 200 is the relative displacement of the two ends of the flexible screen 200 with respect to the two ends of the flattening sheet 2, that is, relative displacement of the second sliding member 322 relative to the end of the first sliding member 321. Through the sliding of the second sliding member 322, in the unfolding process, the second sliding member 322 moves in a direction away from the first sliding member 321 and the folding mechanism 1, then the arc length difference between the flexible screen 200 and the flattening sheet 2 during bending can be compensated. As shown in FIG. 4, in the unfolded state of the foldable display device, the second sliding member 322 moves a maximum distance relative to the first sliding member 321, and in order to ensure normal bending movement of the flattening sheet 2 and the flexible screen 200, at this time, a gap S₂ between the second sliding member 322 and the first sliding member 321 should be greater than or equal to the above relative displacement, i.e.,

$${S}_{2} \geq \frac{{D}_{2} \cdot π}{2} .$$

When the foldable display device is folded into the folded state from the unfolded state, the two ends of the flattening sheet 2 move a larger distance relative to the two ends of the folding mechanism 1, the two ends of the flexible screen 200 move a larger distance relative to the two ends of the flattening sheet 2, the first sliding member 321 moves close to the folding mechanism 1, and the displacement of the first sliding member relative to the end of the folding mechanism 1 is

$$\frac{{D}_{1} \cdot π}{2} ,$$

which can compensate tor the arc length difference between the flattening sheet 2 and the folding mechanism 1; the second sliding member 322 moves close to the first sliding member 321, and displacement of the second sliding member relative to the first sliding member 321 is

$$\frac{{D}_{2} \cdot π}{2} ,$$

which can compensate for the arc length difference between the flexible screen 200 and the flattening sheet 2. The foldable display device provided in the present embodiment is mainly applicable to the case where the flexible screen is folded outwardly, that is, the flexible screen 200 is located outside the whole device after the foldable display device is folded, and after the foldable display device is unfolded, the case where the middle of the flexible screen 200 is arched can be effectively avoided, then the flatness of the flexible screen 200 after the unfolding is ensured; the flatness of the flexible screen can be further ensured by using the flattening sheet 2; by utilizing the movement of the first sliding members 321 and the second sliding members 322 in the two sets of sliding mechanisms 3, the arc length difference caused by different bending radii of the flexible screen 200, the flattening sheet 2, and the folding mechanism 1 can be compensated, thereby avoiding pulling the flexible screen 200, and ensuring the reliability of the flexible screen. Certainly, the foldable display device in the present embodiment may also be applied to the case where the flexible screen is bent inwardly.

The present embodiment further provides a foldable terminal, wherein the foldable terminal includes the foregoing foldable device, and the foldable terminal may be an intelligent terminal product such as a tablet computer, a mobile phone, and a display. The foldable terminal may further include a housing (not shown in the drawings), wherein the housing includes two sub-housings, and the two sub-housings cover the two sets of sliding mechanisms respectively, so as to protect internal structures, and the two sub-housings may be fixedly connected to two ends of the folding mechanism, respectively, and a user may apply a force to the housing so that the whole foldable terminal is unfolded or folded.

The above embodiments do not constitute limitation on the scope of protection of the technical solution. Any amendments, equivalent replacements, improvements and so on, made within the spirit and principle of the above embodiments, should be covered within the scope of protection of the technical solution.

What is claimed is:

1. A foldable display device, comprising a flexible screen, a folding mechanism, a bendable flattening sheet, and two sets of sliding mechanisms, wherein the folding mechanism, the flattening sheet, and the flexible screen are laminated in sequence, and the folding mechanism, the flattening sheet, and the flexible screen are fixedly connected to each other at a middle folding position;
the two sets of sliding mechanisms each comprise a first spring, a first sliding member, a second spring, and a second sliding member, wherein the two first springs are fixedly connected to two ends of the folding mechanism respectively, the first spring, the first sliding member, the second spring, and the second sliding member in each set of sliding mechanism are connected in sequence in a direction away from the folding mechanism, and the first springs and the second springs are configured to generate elastic deformation so as to make the first sliding members and the second sliding members slide; and
two ends of the flattening sheet are fixedly connected to the first sliding members of the two sets of sliding mechanisms respectively, and two ends of the flexible screen are fixedly connected to the second sliding members of the two sets of sliding mechanisms, respectively.

2. The foldable display device according to claim 1, wherein the first springs and the second springs are all coil springs.

3. The foldable display device according to claim 1, wherein each end of the folding mechanism is provided with a first positioning hole, each of the first sliding members is provided with a second positioning hole and a third positioning hole, each of the second sliding members is provided with a fourth positioning hole, two ends of the each first spring are fixed in the first positioning hole and the second positioning hole respectively, and two ends of the each second spring are fixed in the third positioning hole and the fourth positioning hole, respectively.

4. The foldable display device according to claim 1, wherein a plurality of the first springs and a plurality of the second springs are provided, the plurality of first springs are arranged side by side along a folding axis of the folding mechanism, and the plurality of second springs are arranged side by side along the folding axis of the folding mechanism.

5. The foldable display device according to claim 1, wherein each of the first sliding members is in an elongated shape arranged along a folding axis of the folding mechanism.

6. The foldable display device according to claim 1, wherein each of the second sliding members is in a square plate shape.

7. The foldable display device according to claim 6, wherein when the foldable display device is in an unfolded state, the two second sliding members and the flattening sheet together form a support surface for the flexible screen.

8. The foldable display device according to claim 1, wherein each set of the sliding mechanism further comprises a guide rod, one end of the guide rod is fixedly connected to an end of the folding mechanism, an axial direction of the guide rod is set along an arrangement direction of the corresponding first sliding member and the corresponding second sliding member, and the corresponding first sliding member and the corresponding second sliding member are both slidably connected to the guide rod.

9. The foldable display device according to claim 1, wherein the flattening sheet is provided with a middle connecting column at the middle folding position, the folding mechanism is provided with a middle connecting hole at the middle folding position, the middle connecting column is fixed in the middle connecting hole by a middle screw, and the folding mechanism is located between the middle screw and the flattening sheet.

10. The foldable display device according to claim 1, wherein two ends of the flattening sheet are each provided with an end connecting column, the first sliding member of each set of sliding mechanism is provided with an end connecting hole, the end connecting columns at two ends of the flattening sheets are each fixed into the end connecting hole of the first sliding member of the corresponding set of sliding mechanism by an end screw, and each of the first sliding members is located between the middle screw and the flattening sheet.

11. The foldable display device according to claim 1, wherein the folding mechanism comprises a plurality of chain links, the plurality of chain links are hinged in sequence along an arrangement direction of the two sets of sliding mechanisms, a direction of rotation axis of each of the chain links is parallel to a direction of folding axis of the foldable display device, and the chain link located at middle of the plurality of chain links is fixedly connected to the flattening sheet and the flexible screen.

12. The foldable display device according to claim 1, wherein when the first sliding member moves a maximum distance relative to the folding mechanism, a gap between the first sliding member and the folding mechanism is S₁,
$${S}_{1} \geq \frac{{D}_{1} \cdot π}{2} ,$$
where D₁ indicates a distance between neutral layers of the folding mechanism and the flattening sheet when the folding mechanism and the flattening sheet are bent.

13. The foldable display device according to claim 1, wherein when the second sliding member moves a maximum distance relative to the first sliding member, a gap between the second sliding member and the first sliding member is S₂,
$${S}_{2} \geq \frac{{D}_{2} \cdot π}{2} ,$$
where D₂ indicates a distance between neutral layers of the flexible screen and the flattening sheet when the flexible screen and the flattening sheet are bent.

14. A foldable terminal, comprising the foldable display device according to claim 1.

15. The foldable terminal according to claim 14, wherein the first springs and the second springs are all coil springs.

16. The foldable terminal according to claim 14, wherein each end of the folding mechanism is provided with a first positioning hole, each of the first sliding members is provided with a second positioning hole and a third positioning hole, each of the second sliding members is provided with a fourth positioning hole, two ends of the each first spring are fixed in the first positioning hole and the second positioning hole respectively, and two ends of the each second spring are fixed in the third positioning hole and the fourth positioning hole, respectively.

17. The foldable terminal according to claim 14, wherein a plurality of the first springs and a plurality of the second springs are provided, the plurality of first springs are arranged side by side along a folding axis of the folding mechanism, and the plurality of second springs are arranged side by side along the folding axis of the folding mechanism.

18. The foldable terminal according to claim 14, wherein each of the first sliding members is in an elongated shape arranged along a folding axis of the folding mechanism.

19. The foldable terminal according to claim 14, wherein each of the second sliding members is in a square plate shape.

20. The foldable terminal according to claim 19, wherein when the foldable display device is in an unfolded state, the two second sliding members and the flattening sheet together form a support surface for the flexible screen.
